(19) United States
(12) Patent Application Publication
(10) Pub. No.: US 2008/0102589 A1
(43) Pub. Date: May 1, 2008

(54) Method of manufacturing semiconductor device

(75) Inventor: Tomoko Matsuda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/650,416

(22) Filed: Jan. 8, 2007

(30) Foreign Application Priority Data
Nov. 1, 2006 (JP) 2006-003809

(51) Int. Cl. H01L 21/8234

(52) U.S. Cl. 438/308; 257/E21.615

(57) ABSTRACT

A method for improved manufacturing stability of transistors having silicide layers is provided. A gate electrode 105 and a side wall insulating film that covers a side surface of the gate electrode are formed over the device-forming surface of a silicon substrate 101. A source/drain region 109 is formed in a periphery of the gate electrode 105 on the silicon substrate 101. A Ni film 115 is formed on the entire device-forming surface of the silicon substrate 101 that is provided with a side wall 107 formed thereon, and then, a reaction of the silicon substrate 101 with the Ni film 115 on the source/drain region 109 by heating the silicon substrate 101. Thereafter, unreacted portions of the Ni film 115 are removed, and then a Ni silicide layer 111 is formed on the source/drain region 109. In the step for forming the Ni film 115 or in the step for inducing a reaction of the silicon substrate 101 with the Ni film 115 by heating the silicon substrate 101, a broken portion 117, which is provided by breaking the Ni film 115 off, is formed on the side wall 107.

This application is based on Japanese patent application No. 2006-3,809, the content of which is incorporated hereinto by reference.

### BACKGROUND

1. Technical Field

The present invention relates to a method of manufacturing a semiconductor device having a field effect transistor provided on a silicon substrate.

2. Related Art

A technology for forming a silicide layer overlying a silicon substrate is known in conventional processes for manufacturing semiconductor devices. A reduced resistance of a gate electrode and a source/drain layer can be achieved by providing the silicide layer. Typical process for manufacturing such semiconductor device includes technologies described in Japanese Patent Laid-Open No. H10-178,179 (1998) and Japanese Patent Laid-Open No. 2004-289,138.

A technology that attempts to apply silicide for forming a thin electrode is described in Japanese Patent Laid-Open No. H10-178,179. In the technology described in Japanese Patent Laid-Open No. H10-178,179, silicon atom required for creating silicide, is supplied on the transistor electrode in a form of a silicide layer. It is described that this provides forming the silicide layer without consuming silicon of the electrode.

Further, a semiconductor device having pseudo electrodes provided in respective sides of a gate electrode is described in Japanese Patent Laid-Open No. 2004-289,138. In such semiconductor device, a thickness of the silicide layer formed on the gate electrode is larger than a thickness of the silicide layer formed in a region to be located between the adjacent gate electrode and the pseudo electrode. It is described that this provides a uniform thickness of the silicide layer on a source/drain diffusion layer. It is further described that this technology can simultaneously achieve providing an increased film thickness of the silicide film on the gate electrode and providing a reduced film thickness of the silicide film caused by a shallower junction of the source drain diffusion layer.

On the other hand, a typical sputter apparatus employed in a process for forming a silicide layer is described in Japanese Patent Laid-Open No. 2004-263,305. It is described in Japanese Patent Laid-Open No. 2004-263,305 that an installed collimate plate is provided between a target holder and a wafer holder. It is also described that the a charge up of the gate electrode can be inhibited by performing a metal sputter process while the collimate plate is inserted therebetween.

Appropriate silicide material has been selected according to the gate electrode length of the transistor. In order to achieve faster operation of a field effect transistor, scaling down of the transistor gate length is developing. Nickel silicide is commonly used for the CMOS (Complementary Metal Oxide Semiconductor) transistor whose gate length is smaller than 200 nm.

The present inventor attempted applying nickel silicide to more scaled semiconductor device with 60 nm gate length or smaller. However, it was clarified in the attempt that smaller gap between adjacent gate electrodes considerably causes an excessive reaction of nickel with silicon in a region including the smaller gap between the adjacent gate electrodes in the steps for forming a nickel-containing film over a silicon substrate and for inducing a reaction between the silicon substrate and the nickel-containing film to create nickel silicide.

The present inventors actively investigated a reason for considerably inducing an excessive reaction of nickel with silicon in a region including the smaller gap between the adjacent gate electrodes when nickel is employed as silicidation metal. As results of the investigation, two reasons for causing an excessive reaction of nickel with silicon are assumed: NiSi₂ is easily generated in a region of including gate electrodes with dense arrangement; and a “sliding” of Ni atoms from a nickel-containing film deposited on a side wall is easily caused in the reaction.

The latter in the above-described two reasons, which is a phenomenon that is expressed as “sliding” caused in the reaction in this description, is a phenomenon, in which the nickel-containing film deposited on the side wall moves along the surface of the side wall in a reaction of silicidation, and eventually slides down into a source/drain region of the silicon substrate. When the sliding is caused in the silicidation reaction, the nickel-containing film, which has been moved from the side wall, is further supplied into the source/drain region, in addition to the nickel-containing film, which has been initially deposited in the source/drain region. There has been a concern that an excessive reaction would be generated between nickel and the exposed silicon substrate, if an excess amount of nickel-containing film is deposited on the exposed source/drain region.

Such sliding phenomenon is a phenomenon newly discovered by the investigation of the present inventors that employs the nickel-containing film. In order to provide an inhibition to the excessive reaction caused by such nickel-sliding phenomenon, different approaches from that described in Japanese Patent Laid-Open No. H10-178,179 and Japanese Patent Laid-Open No. 2004-289,138 are required. Consequently, the present inventors have further investigated an inhibition of the sliding of Ni atoms from nickel-containing film on the side wall, eventually presenting the present invention.

According to one aspect of the present invention, there is provided a method of manufacturing a semiconductor device, comprising: forming a gate electrode on a device-forming surface of a silicon substrate; forming a side wall insulating film covering a side wall of the gate electrode; forming a source/drain region in vicinity of the gate electrode in the silicon substrate; forming a nickel-containing film over the device-forming surface of the silicon substrate having the side wall insulating film formed thereon; inducing a reaction between the silicon substrate and the nickel-containing film on the exposed source/drain region by heating the silicon substrate having the nickel-containing film formed thereon; and forming a silicide layer on the exposed source/drain region by removing unreacted portion of the nickel-containing film, after the inducing a reaction between the silicon substrate and the nickel-containing film; wherein, in the forming the nickel-containing film or in the inducing the reaction between the silicon substrate and the nickel-containing film by heating the silicon substrate, a broken portion is formed on the side wall insulating film, the broken portion being provided by breaking the nickel-containing film off.

In the manufacturing method according to the present invention, the nickel-containing film on the side wall insulating film is broken off to form the broken portion, during or after forming the nickel-containing film. This configuration provides a prevention of a portion of the nickel-containing film formed on the side wall insulating film formed above the broken portion from being slid into the source/drain region of the silicon substrate. Thus, an excessive supply of the nickel-containing film to the source/drain region can be inhibited. Therefore, an excessive reaction between the silicon substrate and the nickel-containing film in the source/drain region can be inhibited. Consequently, according to the present invention, the silicide layer containing nickel can be formed on the source/drain region with an improved manufacturing stability. Further, since the inhibition of the excessive reaction promotes an effective inhibition of a reduction in the depth of the source/drain region, a generation of a junction leakage current in the source/drain region can be inhibited.

In addition to above, in the manufacturing method according to the present invention, the broken portion of nickel-containing film may be formed in at least a region in the side wall insulating film. Further, since the broken portion is formed along a direction of an elongation of the gate electrode from an upper viewpoint, the sliding phenomenon of the Ni atoms from nickel-containing film can be more effectively inhibited.

Although the reason for causing the sliding phenomenon in the nickel-containing film, is not necessarily clarified, it is considered that a relatively lower affinity of the side wall insulating film with the nickel-containing film causes the sliding phenomenon.

It is to be understood that the invention is capable of using in various other combinations, modifications and environments, and any other interchanges in the expression between the method and device or the like according to the present invention may be effective as an alternative of an embodiment according to the present invention.

As described above, according to the present invention, a technology for providing an improved manufacturing stability of transistors having a silicide layer can be achieved.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, illustrating a configuration of a semiconductor device in an embodiment;

FIGS. 2A to 2C are cross-sectional views, illustrating a process for manufacturing the semiconductor device of FIG. 1;

FIGS. 3A to 3C are cross-sectional views, illustrating a process for manufacturing the semiconductor device of FIG. 1;

FIGS. 4A and 4B are cross-sectional views, illustrating a process for manufacturing the semiconductor device of FIG. 1;

FIGS. 5A to 5C are cross-sectional views, illustrating a configuration of a gate electrode of the semiconductor device in an embodiment; and

FIGS. 6A and 6B are graphs, showing relationships of the Ni film thickness for causing a break with a first sintering temperature in the semiconductor device of the example.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows in further detail, in reference to the annexed figures. In all figures, identical numeral is assigned to an element commonly appeared in the figures, and the detailed description thereof will not be repeated.

### First Embodiment

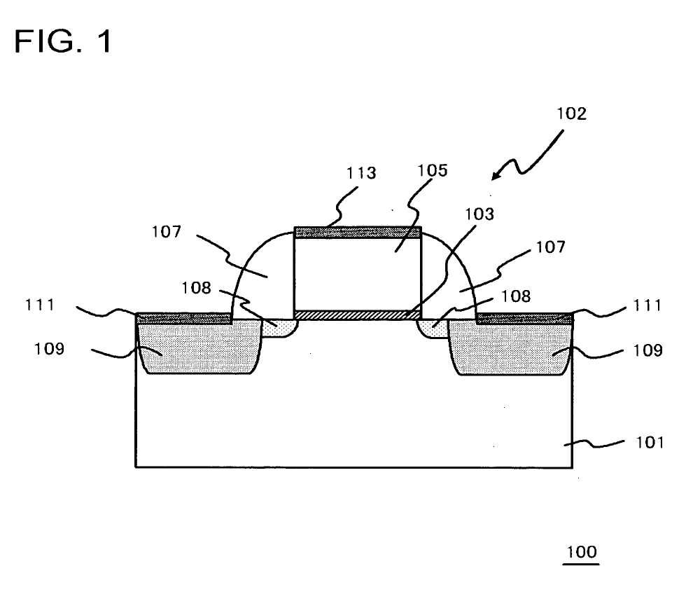

FIG. 1 is a cross-sectional view, illustrating a configuration of a semiconductor device of the present embodiment. A semiconductor device 100 shown in FIG. 1 includes a silicon substrate 101 and a metal oxide semiconductor field effect transistor (MOSFET) 102 provided on the silicon substrate 101.

The MOSFET 102 includes a pair of source/drain regions 109 provided in vicinity of a surface of the silicon substrate 101, an SD-extension (source/drain extension) region 108 formed above the source/drain region 109, a channel region (not shown) formed between these regions, a gate insulating film 103 provided on the channel region, a gate electrode 105 provided on gate insulating film 103 and a side wall 107 covering the side walls of the gate insulating film 103 and the gate electrode 105. Further, a nickel (Ni) silicide layer 113 is provided above the gate electrode 105. Further, the Ni silicide layer 113 is provided on the exposed the source/drain region 109 provided except for the side wall 107 formation area.

The gate insulating film 103 may be, for example, an oxide film such as silicon dioxide (SiO₂) film or a an oxynitride film such as silicon oxynitride (SiON) film. In the following description, an exemplary implementation of employing an SiO₂ film for the gate insulating film 103 will be described. In addition, a high dielectric constant film may be employed for the gate insulating film 103. The high dielectric constant film is a film having higher relative dielectric constant than that of silicon oxide film, and so-called high-k film may be typically employed. The high dielectric constant film may be composed of a film having relative dielectric constant of equal to or higher than 6. More specifically, the high dielectric constant film may be compose of a material containing one or more metallic element(s) selected from a group consisting of hafnium (Hf) and zirconium (Zr), and may also be an oxide film or a silicate film containing one or more of the above-described metallic elements.

The gate electrode 105 is composed of an electrically conducting film containing silicon. The gate electrode 105 is, more specifically, composed of a polycrystalline silicon film.

The side wall 107 is composed of an insulating film. A material for forming the side wall 107 is, for example, an oxide film such as SiO₂ film or a nitride film such as silicon nitride (SiN) film. The side wall 107 is expanded toward the surface of the silicon substrate 101 from the upper portion of the gate insulating film 103.

The source/drain region 109 is a dopant-diffused region functioning as a drain or a source of the MOSFET 102.

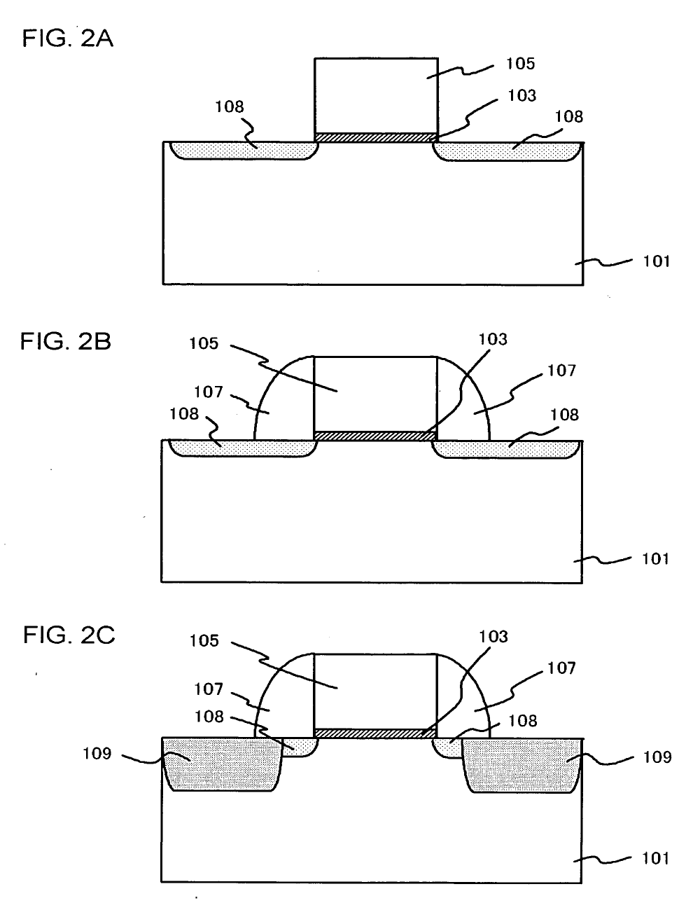

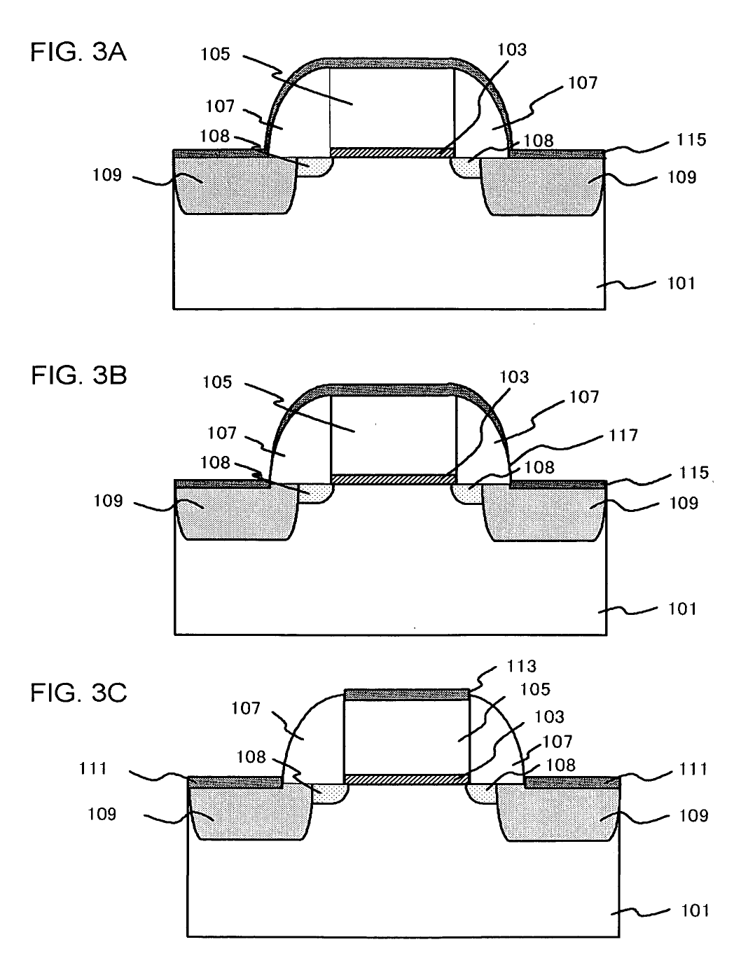

Next, the method of manufacturing the semiconductor device 100 shown in FIG. 1 will be described. FIG. 2A to FIG. 2C and FIG. 3A to FIG. 3C are cross-sectional views, illustrating a procedure for manufacturing the semiconductor device 100. The semiconductor device 100 is obtained by forming the MOSFET 102 on the silicon substrate 101.

Semiconductor device 100 is produced by the following procedures:

Step 101: a step for forming the gate electrode 105 over the device-forming surface of the silicon substrate 101;

Step 103: a step for forming a side wall insulating film that covers a side surface of the gate electrode 105 (i.e., side wall 107);

Step 105: a step for forming the source/drain region 109 in a periphery of the gate electrode 105 over the silicon substrate 101;

Step 107: a step for forming a nickel-containing film (Ni film 115) over the entire device-forming surface of the silicon substrate 101 that is provided with the side wall 107 formed thereon;

Step 109: a step for inducing a reaction of the silicon substrate 101 with the Ni film 115 on the exposed source/drain region 109 by heating the silicon substrate 101 having the Ni film 115 formed thereon; and

Step 111: a step for forming a silicide layer (Ni silicide layer 111) on the exposed source/drain region 109 after unreacted portions of the Ni film 115 is removed, which is carried out after the operation of the step 109 for inducing the reaction between the silicon substrate 101 and the Ni film 115 is performed.

Among the above-described steps, in the step 107 for forming the Ni film 115 or in the step 109 for inducing a reaction of the silicon substrate 101 with the Ni film 115 by heating the silicon substrate 101, a broken portion 117, which is provided by breaking the Ni film 115 off, is formed on the side wall 107.

In the step 107 for forming the Ni film 115 or in the step 109 for inducing a reaction of the silicon substrate 101 with the Ni film 115 by heating the silicon substrate 101, the broken portion 117 is formed along a direction of an elongation of the gate insulating film 103 from the upper viewpoint. Further, the broken portion 117 is provided to form a stripe pattern from one end to another end of the side wall 107 from the upper viewpoint. This can ensure further inhibition of the sliding of Ni into the silicon substrate 101.

In this regard, in the present embodiment and the following embodiments, it is sufficient to provide the broken portion 117 in at least a region on the side wall 107. The broken portion 117 is provided from one end to another end of the side wall 107 as in the present embodiment, such that a sliding of Ni can be inhibited over the whole of the side wall 107 along a direction of the elongation thereof. Consequently, an excessive reaction of the silicon substrate 101 with the Ni film 115 in the source/drain region 109 can be more effectively inhibited.

In addition, in the step 107 for forming the Ni film 115 or in the step 109 for inducing a reaction of the silicon substrate 101 with the Ni film 115 by heating the silicon substrate 101, the broken portion 117 is formed on the side wall 107 in both sides of the gate insulating film 103. Having such configuration, further inhibition of the sliding of Ni into the silicon substrate 101 in both sides of the gate electrode 105 can be ensured. Consequently, structural differences in both sides of the gate electrode 105 of the semiconductor device 100 can be more effectively inhibited.

The broken portion 117 is formed in vicinity of the bottom of the side wall 107. Here, the vicinity of the bottom the side wall 107 means that it is near the bottom of the side wall 107, such that the sliding of the Ni atoms from Ni film 115 on the side wall 107 into the source/drain region 109 can be sufficiently inhibited to provide the product for a practical use.

The gate electrode 105 of the semiconductor device 100 contains silicon, and a reaction of the gate insulating film 103 with the Ni film 115 is induced in the step 109 for inducing a reaction of the silicon substrate 101 with the Ni film 115 by heating the silicon substrate 101, and the Ni silicide layer 111 and the Ni silicide layer 113 are formed on the exposed the source/drain region 109 and on the gate insulating film 103, respectively, in the step 111 for forming the Ni silicide layer 111. This can provide a reduced electrical resistance of the gate insulating film 103, in addition to providing a reduced electrical resistance of the source/drain region 109.

In the present embodiment, the step 109 for inducing a reaction of the silicon substrate 101 with the Ni film 115 by heating the silicon substrate 101 includes heat-treating the silicon substrate 101 in a first condition, and breaking the Ni film 115 on the side wall 107 off to form the broken portion 117.

In addition, in the present embodiment, the step 111 for forming the Ni silicide layer 111 includes:

Step 113: a step for removing unreacted portion of the Ni film 115; and

Step 115: a step for inducing a reaction of the silicon substrate 101 with the Ni film 115 by heating the silicon substrate 101 in a second condition, after performing the step 113 for remove the unreacted portion of the Ni film 115.

In addition to above, it is sufficient that the heat treatment process in the first condition of the step 109 is performed in a condition, in which the broken portion 117 is formed. In addition, such heat treatment process is performed in a condition, in which the reaction of the silicon substrate 101 with the Ni film 115 is induced. More specifically, in the step 107 for forming the Ni film 115, a region including the Ni film 115 having a film thickness of equal to or thinner than 5 nm is formed on the side wall 107. Then, in the step 109 for heat-treating the silicon substrate 101 in a first condition to form the broken portion 117, the silicon substrate 101 is heat-treated at a temperature within a range of from 250 degree C. to 500 degree C. By heating the silicon substrate 101 at a temperature of not lower than 250 degree C., a thermal cohesion of the Ni film 115 can be more surely created, so that the formation of the broken portion can be further ensured. In addition, by heating the silicon substrate 101 at a temperature of not higher than 500 degree C., a stable silicidation reaction can be performed in further moderate condition.

Hereinafter, the procedure for manufacturing the semiconductor device 100 will be more specifically described in reference to FIG. 2A to FIG. 2C and FIG. 3A to FIG. 3C.

First of all, as shown in FIG. 2A, an element isolation region of a shallow trench isolation (STI) (not shown) is formed by a known technology on a surface of the silicon substrate having a principal surface of (100) plane. The element isolation region may be formed by other known method such as local oxidation of silicon (LOCOS) process or the like. Thereafter, an oxide film is formed on the silicon substrate 101 by a thermal oxidation process. Then, a polycrystalline silicon film having a film thickness of, for example, about 50 to 200 nm is formed on the oxide film.

Next, a photo resist film is formed over the silicon substrate 101 and then the photo resist film is patterned by conventional lithography process. The polycrystalline silicon film and the oxide film are selectively dry etched off using the patterned photo resist film as a mask, so that the polycrystalline silicon film and the oxide film are formed to have the geometries of the gate insulating film 103 and the gate electrode 105 (step 101).

Then, an ion implantation process is carried out through a mask of the gate electrode 105 to form the SD-extension region 108, which functions as an electrical coupling between the channel region and the source/drain region 109 (FIG. 2A).

Subsequently, as shown in FIG. 2B, an insulating film, which serves as the side wall 107, is deposited on the device-forming surface of the silicon substrate 101 by a chemical vapor deposition (CVD) process to cover the gate electrode 105. A material for forming the insulating film is, for example a silicon oxide film or a nitride film. In addition, a film thickness of the insulating film is, for example, about 10 to 100 nm. The insulating film is etched back in a predetermined condition to form the side wall 107 on both sides of the gate electrode 105 (step 103).

Then, as shown in FIG. 2C, dopant having a conductivity type that is same as the conductivity type of the dopant injected into the SD-extension region 108 is ion-implanted into the silicon substrate 101 through a mask of the gate electrode 105 and the side wall 107. The source/drain region 109, which is deeper than the SD-extension region 108, is formed in periphery of the gate electrode 105 by conducting such ion implantation process (step 105).

Subsequently, the dopant in the source/drain region 109 is activated by a spike rapid thermal annealing (spike RTA) process. Highest reachable temperature in the surface of the silicon substrate 101 during the spike RTA process is, for example, about 1,000 to 1,100 degree C. Thereafter, a predetermined nickel sputter pre-processing may be performed over the device-forming surface of the silicon substrate 101. Typical pre-processing includes, for example, a cleaning process for the surface of the silicon substrate 101 employing a liquid chemical solution. The cleaning process removes a native oxide film or a contaminant formed on the surface of the silicon substrate 101, so that a silicidation of a region on the source/drain region 109 can more surely be performed.

Next, as shown in FIG. 3A, the Ni film 115 is formed on entire surface of the device-forming surface of the silicon substrate 101 by employing a sputter process (step 107). In this case, a film thickness of a portion of the Ni film 115 on the source/drain region 109 may be about 5 to 20 nm, and more specifically about 7 to 15 nm. The Ni film 115 may be formed by, for example, a sputter process at ambient temperature. In addition, in this case, a film thickness of a portion of the Ni film 115 on the lower portion of the side wall 107 is reduced to a thickness that enables forming the broken portion 117 by a sintering process as discussed later. The formation of the broken portion 117 can be ensured in the step 109 by providing the region having the suitable film thickness for forming the broken portion 117 in the Ni film 115 on the side wall by the sintering process.

Upper limit of the film thickness of the Ni film 115 on the side wall 107 for forming the broken portion 117 in the Ni film 115 on the side wall by the sintering process depends upon, for example, a geometry of the side wall 107 such as a rising angle α of the surface of the side wall 107 in the bottom of the side wall 107 over the surface of the silicon substrate 101, a type of a material of the side wall 107 and a sintering temperature. The method of forming the broken portion 117 will be described in detail in examples as discussed later. In the present embodiment, the Ni film 115 is deposited in a condition of, for example, selecting 60 degrees for the rising angle of the surface of the side wall 107 in vicinity of the bottom of the side wall 107 and in a condition for forming the region having the film thickness of the Ni film 115 of equal to or less than 5 nm on the side wall 107.

The film thickness of the Ni film 115 formed on the lower portion of the side wall 107 may be adjusted by, for example, changing a substrate bias voltage during the sputter process, when an ionization sputter process is employed. In addition, when an ordinary sputter process is employed, the film thickness of the Ni film 115 formed on the lower portion of the side wall 107 may be adjusted by adjusting anisotropy of sputter with a collimate board. When anisotropy of the sputter process is enhanced with only a collimate board, a diameter of opening of the collimate board and a thickness of the collimate board are suitably controlled. More specifically, thicker collimate board and smaller hole diameter provides higher anisotropy of the sputter process, such that thinner Ni film 115 adhered to the side wall 107 can be achieved.

In addition, anisotropy of the sputter process is suitably adjusted according to the geometry of the side wall 107. Lower height of the gate electrode 105 and thicker side wall 107 provides a gentle geometry of the lower portion of the side wall. Consequently, it is required to performed a sputter process of higher anisotropy, for the purpose of providing a reduced film thickness of the portion of the Ni film 115 on the lower portion of the side wall 107 in the process for forming the Ni film 115. Meanwhile, when the height of the gate electrode 105 is higher and the film thickness of the side wall 107 is thinner, the geometry of the lower portion of the side wall is steep. Consequently, even if anisotropy of the sputter process is relatively lower, a reduced film thickness of the Ni film 115 formed on the lower portion of the side wall 107 can be achieved.

In succession to the sputter process of the Ni film 115, titanium nitride (TiN) may be sputtered to a thickness of about 5 to 10 nm for the purpose of providing an anti-oxidation of the surface of the Ni film 115.

Subsequently, as shown in FIG. 3B, the silicon substrate having the Ni film 115 formed thereon is heat-treated to form the broken portion 117 (step 109). In the present embodiment, two-step sintering process is performed. In the step 109, a first sintering process (step 113) is performed. In the first sintering process, an annealing at a lower temperature is performed to generate a film cohesion in the Ni film 115 formed on the side wall 107, thereby forming the broken portion 117 and forming metastable Ni silicide.

Heating temperature for forming the broken portion 117 depends upon the film thickness of the Ni film 115 on the side wall 107 or the like. For example, when the rising angle of the surface of the side wall 107 in vicinity of the bottom of the side wall 107 is 60 degree and the film thickness of the Ni film 115 on the side wall 107 is equal to or less than 5 nm, the sintering temperature in the first sintering process is selected to be within a rage of from 250 degree C. to 500 degree C. and the sintering process time is selected to be longer than 0 second and not longer than 60 seconds.

Subsequently, as shown in FIG. 3C, unreacted portions of the Ni film 115 is removed by a wet etch process (step 113). Thereafter, an annealing process of the silicon substrate 101 is performed at a predetermined temperature as the second sintering process a reaction of Ni with Si is induced to form silicide (step 115). The temperature of the second sintering process is selected to be higher than a temperature of the first sintering process, for example. The semiconductor device 100 shown in FIG. 1 is obtained by the above-mentioned procedure. In addition to above, after the above-mentioned procedure, an additional operation for forming a contact plug in a predetermined location of the semiconductor device 100 or an additional predetermined interconnect operation may be performed.

According to the present embodiment, the broken portion 117 is formed on the side wall 107 during the silicidation reaction of the Ni film 115. In conventional technologies, the processes are not designed for intentionally forming the broken portion 117, as a geometry of the lower portion of the side wall is gentle, or as an anisotropy of the nickel sputter operation is lower. Consequently, larger amount of quantity of nickel is deposited on the side wall, and thus an excessive reaction of Ni and Si is promoted in a region including a smaller gap between the adjacent gate electrodes.

On the contrary, since the broken portion 117 is formed in the operation of Ni silicidation in the step 109 according to the present embodiment, a sliding of the Ni atoms from Ni film 115 formed above the broken portion 117 into the silicon substrate 101 under the side wall 107 can be avoided. Consequently, even if the configuration of having a smaller spacing between the adjacent gates is employed, an excessive reaction of the silicon substrate 101 with Ni on the source/drain region 109 can be inhibited. More specifically, in a case of employing a semiconductor device, in which a length of equal to or less than 0.16 μm is selected for a width of a diffusion layer on the surface of the silicon substrate in a cross sectional view in a direction along the gate length, or more specifically selected for a spacing between a side edge of the gate electrode the diffusion layer and a side edge of the element isolation film on the surface of the silicon substrate, an influence of the sliding of Ni from the side wall in particular is considerably created. According to the present embodiment, even if such miniaturized configuration is employed, a sliding of the Ni atoms from Ni film 115 from the side wall 107 above the source/drain region 109 can be inhibited. Thus, an improved manufacture stability of the semiconductor device 100 can be provided.

In addition, since a sliding of the Ni atoms from Ni film 115 can be inhibited according to the present embodiment, an excessive reaction of Ni with the silicon substrate 101 in vicinity of the region for forming the side wall 107 can be inhibited. Consequently, a decrease in depth of the source/drain region 109 in vicinity of the region for forming the side wall 107 during forming the Ni silicide layer 111 can be inhibited. Consequently, a generation of a junction leakage current in the source/drain region 109 can be effectively inhibited.

In addition, in the present embodiment, the Ni film 115 is formed a sputter process at ambient temperature. Consequently, if a wet treatment is carried out just after the sputter of Ni under a condition that promotes removing nickel from the side wall, all of nickel would be removed therefrom, unlikely in the case for depositing a silicide layer on an electrode described in Japanese Patent Laid-Open No. H10-178,179. Consequently, in the present embodiment, the Ni film 115 is formed, and the silicidation reaction is performed by the first sintering process, and then, unreacted portion of the Ni film 115 is removed by a wet process. Having such procedure, unreacted portion of the Ni film 115 on the side wall 107 can be selectively removed.

In addition, in the present embodiment, the heat treatment process for silicidation is performed by a two-step process including a first sintering process and a second sintering process. In the first sintering process, a relatively lower temperature is selected for the heating temperature, so that the broken portion 117 can be stably formed and the silicidation reaction can be stably proceeded with a moderate condition. Consequently, an improved manufacture stability for the Ni silicide layer 111 and the Ni silicide layer 113 can be provided.

In the following second embodiment, descriptions will be made by focusing differences of the configuration from first embodiment.

### Second Embodiment

The present embodiment relates to another type of method of manufacturing the semiconductor device 100 (FIG. 1). Basic procedures in the process for manufacturing the device according to the present embodiment is similar to that of first embodiment, except that a method of forming the broken portion 117 is different there from. While the broken portion 117 is formed in the Ni film 115 in the step 109 in first embodiment, the present embodiment involves forming the Ni film 115 originally having the broken portion 117 in the step 107.

In the present embodiment, an interception surface that provides an inhibition of an adhesion of the Ni film 115 is formed on the side wall 107 in the step 103 for forming the side wall 107, and the broken portion 117 is formed above the interception surface of the side wall 107 in the step 109 for forming the Ni film 115.

A step for forming the interception surface includes forming the side wall 107 so that a rising angle of a surface of the side wall 107 in a bottom of the side wall 107 over a surface of the silicon substrate 101 is substantially 90 degree. In addition, in the step 109 for forming the Ni film 115, the broken portion 117 is formed in the bottom of the side wall 107.

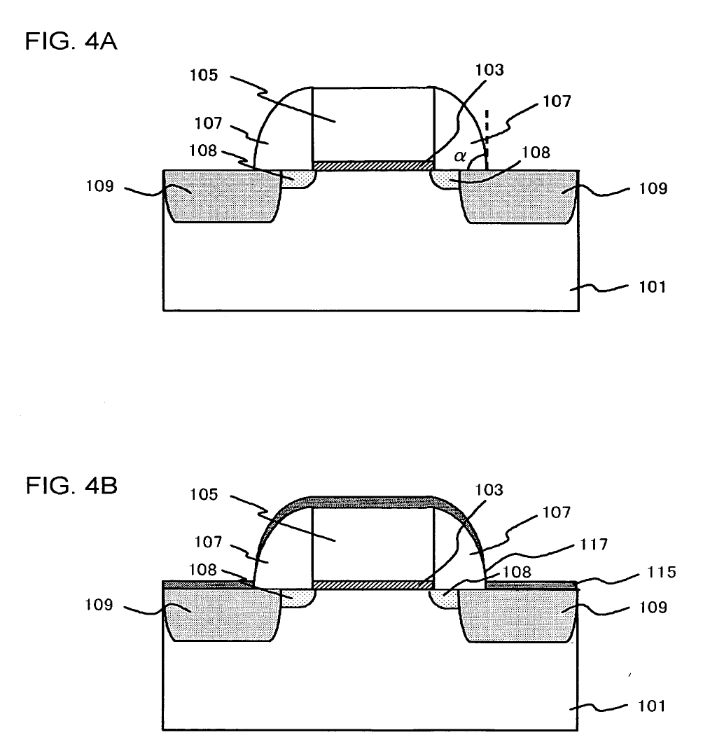

FIG. 4A and FIG. 4B are cross-sectional views, illustrating a process for manufacturing the semiconductor device 100 of the present embodiment. Also in the present embodiment, the gate insulating film 103, the gate electrode 105, the side wall 107, the SD-extension region 108 and the source/drain region 109 are formed in predetermined region on silicon substrate 101 by employing the procedure described above in reference to FIG. 2A to FIG. 2C.

However, in the present embodiment, conditions for etching back the insulating film is suitably controlled when the side wall 107 is formed, so that geometry of the lower portion of the side wall 107 has a steep angle over the silicon substrate 101. Then, anisotropy in the Ni sputter process is enhanced so that the as-sputtered Ni film 115 is so thin that the Ni film 115 is substantially not a film.

The rising angle α of the side wall 107 in the present invention is, more specifically, an angle α between a tangent of the side wall 107 drawn from the surface of the silicon substrate 101 and the surface (horizontal plane) of the silicon substrate 101, as shown in FIG. 4A. The rising angle α may be measured by, for example, observing a cross section of the semiconductor device 100 along the gate length direction by a scanning electron microscope (SEM).

In addition to above, in the process for manufacturing transistors having a gate length of equal to or less than 100 nm, an influence of a thermal processing performed after the formation of a junction in geometrical changes is low, and the rising angle α formed in the step of the silicide formation is generally maintained after the semiconductor device is completed.

In the present embodiment, the rising angle α is selected to be 90 degrees. By selecting 90 degrees for the rising angle α, the surface of the side wall 107 is served as the interception surface, on which the Ni film 115 is not adhered, in vicinity of the bottom of the side wall, and at least a portion of the interception surface can be provided with the broken portion 117. Then, anisotropy in the sputter process for forming the Ni film 115 is enhanced, so that a quantity of the sputtered material from directions other than a direction perpendicular to the silicon substrate 101 is reduced. Having such procedure, a formation of the Ni film 115 in vicinity of the bottom of the side wall 107 can be avoided (FIG. 4B).

In addition to above, the rising angle of the side wall 107 can be adjusted by adjusting conditions of the dry etch process for an insulating film serving as the side wall 107. Such etch condition includes, specifically, type and pressure of etchant gases. For example, when the side wall 107 having an ordinary gentle slope is formed, a gaseous mixture of carbon tetrafluoride (CF₄), carbon trifluoride (CHF₃), oxygen (O₂) and argon (Ar) is employed for an etchant gas, and relatively lower pressure in a chamber is employed for performing the etch process. On the contrary, in the present embodiment, a gaseous mixture of perfluoro butene (C₄F₈), O₂ and Ar is employed for an etchant gas, and relatively higher pressure in a chamber is employed for performing the etch process, so that steeper slope of the side wall 107 can be created.

More specifically, the gaseous mixture of CF₄, CHF₃, O₂ and Ar is employed for the etchant gas, so that the rising angle α of the side wall 107 can be 90 degrees. In addition, a gaseous mixture of CHF₃, O₂ and Ar may also be employed. More specifically, etching pressure may be about 20 to 100 mTorr, and volumetric flow rates of gases: CHF₃/O₂/Ar may be 20/20/300 sccm. This can provide a formation of the side wall 107 having a bottom that vertically rises from the silicon substrate 101 in one-stage etch process.

In addition to above, also in the present embodiment, a procedure for providing an improved anisotropy in the sputter process for the Ni film 115 described in first embodiment may be employed.

While the preferred embodiments of the present invention have been described above in reference to the annexed figures, it should be understood that the disclosures above are presented for the purpose of illustrating the present invention, and various configurations other than the above described configurations can also be adopted.

While a case of forming the Ni film 115 on the silicon substrate 101 in order to form the Ni silicide layer 111 has been described as an exemplary implementation in the above-mentioned embodiment, for example, it is sufficient that a film to be formed on the silicon substrate 101 is a nickel-containing film, and for example, a nitride film such as nickel(II) nitride (NiN) film and the like or a metallic film containing Ni may be employed. While polycrystalline silicon is employed for the material of the gate electrode 105 in the above-described embodiment, various types of materials may also be employed for the gate electrode 105.

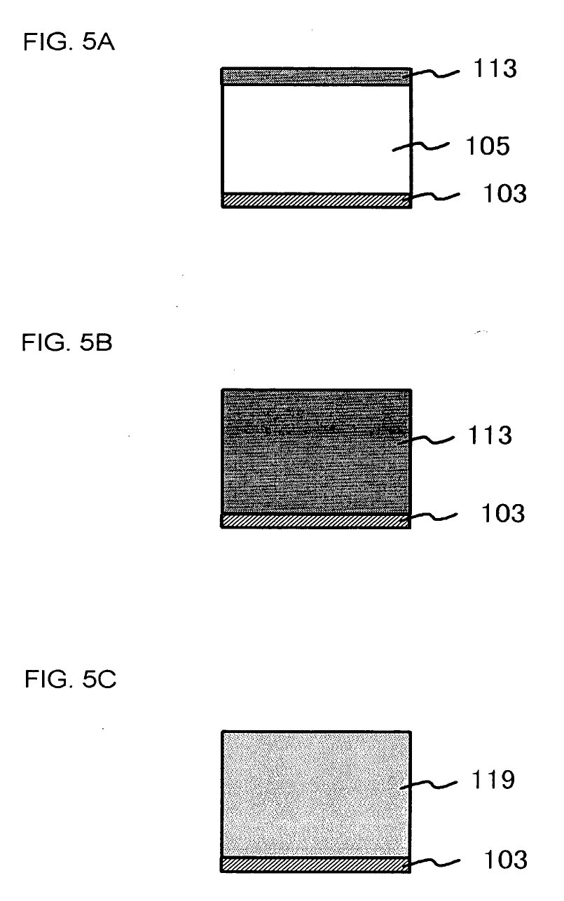

FIG. 5A to FIG. 5C are diagrams, illustrating a configuration of the gate electrode of the semiconductor device 100. FIG. 5A corresponds to the configuration of the semiconductor device 100 shown in FIG. 1. In FIG. 5A, the material of the gate electrode 105 is polycrystalline silicon, and the Ni silicide layer 113 is formed thereon. In addition, in FIG. 5B, the gate electrode is composed of the Ni silicide layer 113. Further, in FIG. 5C, a gate electrode composed of a metallic film 119 is provided. The gate electrode composed of the metallic film 119 may be obtained by, for example, following procedure. First of all, the semiconductor device 100 shown in FIG. 1 is obtained. Thereafter, a mask of an insulating film or the like is formed on the device-forming surface of the silicon substrate 101 so as to cover regions thereof except the region above the gate electrode 105. Then, the Ni silicide layer 113 and the gate electrode 105 are consecutively removed by employing the mask. Thereafter, the metallic film 119 is selectively formed in the region where the Ni silicide layer 113 and the gate electrode 105 have been removed. Alternatively, when the semiconductor device shown in FIG. 1 is formed, the gate electrode 105 may be formed with a material that is easily etched in the post processing, and then the material is etched, and the region where the material has been etched may be plugged with the metallic film 119.

### EXAMPLES

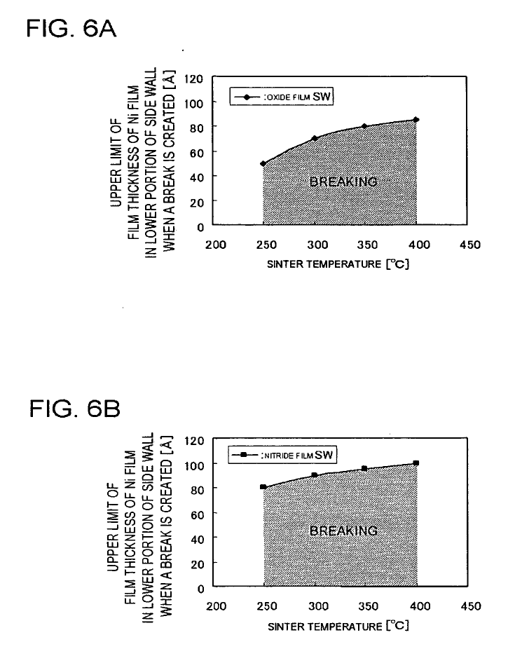

In the present example, the semiconductor device 100 (FIG. 1) was manufactured by employing the method described in first embodiment. An SiO₂ film was employed for the material of the side wall 107. The rising angle α of the side wall 107 was selected to be 60 degrees. Under such conditions, a relationship between a sintering temperature for causing a break of the Ni film 115 on the side wall 107 and a film thickness of the Ni film 115 on side wall 107 when a break was created was investigated. Results are shown in FIG. 6A and FIG. 6B. FIG. 6A shows a result when the side wall 107 (indicated as “SW” in the graph) is an oxide film (SiO₂ film), and FIG. 6B shows a result when the side wall 107 is a nitride film (SiN film).

A break of Ni is caused in a region below solid lines in FIG. 6A and FIG. 6B, and therefore a sliding of Ni can be inhibited by selecting the Ni film thickness of thinner than the solid line.

In addition, as can be seen from FIG. 6A and FIG. 6B, when an SiN film, for example, is used for the material of the side wall, the film thickness for causing a break is slightly increased but a temperature dependency similar as an SiO₂ film has is obtained.

When an excessive reaction is created in the first sintering process, nickel sputtered on the side wall is steadily supplied to the diffusion layer under the side wall. On the contrary, when the film thickness of nickel under the side wall is thinner, the film is aggregated by a heat, and a break of the Ni film 115 is caused on the side wall 107. Once the break of the film is caused, no unreacted nickel is supplied on the diffusion layer that serves as the source/drain region 109, thereby preventing an excessive reaction on the diffusion layer.

When the sintering temperature is selected to be within a range of from 250 degree C. to 400 degree C., a sputter process for the Ni film 115 is performed under a condition, in which the film thickness of the Ni film 115 on the side wall 107 is thinner than the film thickness corresponding to a spot in respective sintering process temperatures in FIGS. 6A and 6B. Having such procedure, the broken portion 117 can be formed on the side wall 107.

The angle of the lower portion of the side wall 107 over the silicon substrate 101 was selected to be 60 degree in the present example, for example. Further, when the Ni film 115 having a film thickness of 10 nm was deposited on the silicon substrate 101 (source/drain region 109) by employing a sputter process, a collimate board thickness was selected to be 107 mm, and hole diameters of the collimate board was selected to be equal to or lower than 1 cm. Having such configuration, the film thickness of the Ni film 115 on the side wall 107 was provided to be equal to or lower than 5 nm.

In addition, thicker collimate board with a reduced hole diameter may be employed to further enhance anisotropy of the sputter process. In addition, in such case, smaller hole diameter of the collimate board provides a tendency of reduced productivity, and therefore the use of the collimate board is limited only for a charging-up countermeasure, and other methods such as an ionization sputter process or the like may be combined therewith. It is apparent that the present invention is not limited to the above embodiment, and may be modified and changed without departing from the scope and spirit of the invention.

What is claimed is:

1. A method of manufacturing a semiconductor device, comprising:
forming a gate electrode over a device-forming surface of a silicon substrate;
forming a side wall insulating film covering a side wall of said gate electrode;
forming a source/drain region in vicinity of said gate electrode in said silicon substrate;
forming a nickel-containing film over said device-forming surface of said silicon substrate having said side wall insulating film formed thereon;
inducing a reaction between said silicon substrate and said nickel-containing film in said source/drain region by heating said silicon substrate having said nickel-containing film formed thereon; and
forming a silicide layer on the said exposed source/drain region by removing unreacted portion of said nickel-containing film, after said inducing a reaction between the silicon substrate and the nickel-containing film;
wherein, in said forming the nickel-containing film or in said inducing the reaction between the silicon substrate and the nickel-containing film by heating the silicon substrate, a broken portion is formed on said side wall insulating film, said broken portion being provided by breaking said nickel-containing film off.

2. The method of manufacturing the semiconductor device according to claim 1, wherein, in said forming the nickel-containing film or in said inducing the reaction between the silicon substrate and the nickel-containing film by heating the silicon substrate, said broken portion is formed along a direction of an elongation of said gate electrode from an upper viewpoint.

3. The method of manufacturing the semiconductor device according to claim 1, wherein, in said forming the nickel-containing film or in said inducing the reaction between the silicon substrate and the nickel-containing film by heating the silicon substrate, said broken portion is formed on said side wall insulating film of respective sides of said gate electrode.

4. The method of manufacturing the semiconductor device according to claim 1, wherein said gate electrode includes silicon, and wherein, in said inducing the reaction between the silicon substrate and the nickel-containing film by heating the silicon substrate, a reaction between said gate electrode and said nickel-containing film is induced, and in said forming the silicide layer, a silicide layer is formed on said source/drain region and on said gate electrode.

5. The method of manufacturing the semiconductor device according to claim 1,
wherein said inducing the reaction between the silicon substrate and the nickel-containing film by heating the silicon substrate includes:
heat-treating said silicon substrate in a first condition to break said nickel-containing film on said side wall insulating film off, thereby forming said broken portion; and
wherein said forming the silicide layer includes: removing unreacted portion of said film containing unreacted said nickel; and
heat-treating said silicon substrate in a second condition, after said removing unreacted portion of said film containing unreacted said nickel.

6. The method of manufacturing the semiconductor device according to claim 5, wherein said forming the nickel-containing film includes: forming a region including said nickel-containing film having a thickness of equal to or less than 5 nm on said side wall insulating film, and wherein said heat-treating the silicon substrate in the first condition to form the broken portion includes:
heat-treating said silicon substrate at a temperature within a range of from 250 degree C. to 500 degree C.

7. The method of manufacturing the semiconductor device according to claim 1, wherein said forming the side wall insulating film includes forming an interception surface for inhibiting an adhesion of said nickel-containing film on said side wall insulating film, and wherein said forming the nickel-containing film includes forming said broken portion above said interception surface of said side wall insulating film.

8. The method of manufacturing the semiconductor device according to claim 7,
wherein said forming the interception surface includes forming said side wall insulating film so that a rising angle of a surface of said side wall insulating film in a bottom of said side wall insulating film over a surface of said silicon substrate is substantially 90 degree, and
wherein said forming the nickel-containing film includes forming said broken portion in said bottom of said side wall insulating film.
